(19) United States
(12) Patent Application Publication
(10) Pub. No.: US 2011/0127060 A1
(43) Pub. Date: Jun. 2, 2011

(54) FACEPLATE WITH HIGH BINDING CAPABILITY

(76) Inventor: Jia-Fei PAN, Taoyuan Hsien (TW)

(21) Appl. No.: 12/628,716

(22) Filed: Dec. 1, 2009

(51) Int. Cl. H05K 5/03

(52) U.S. Cl. 174/66

(57) ABSTRACT

A faceplate with high binding capability comprises a flexible outer layer, a metal plate, and a connection element. The internal surface of the flexible outer layer is correspondingly adhered to the external surface of the metal plate via an adhesive layer. The metal plate is provided with at least a positioning hole throughout the metal plate. The external opening's width of the positioning hole is wider than the internal opening's width thereof. Thereby, after being shaped, the connection element can be firmly connected to the internal surface of the metal plate. The connection element has at least a connection part, so that the faceplate can be firmly connected to a 3C (computer, communication, and consumer-electronics) product.

### TECHNICAL FIELD

The present invention relates to a faceplate and, more particularly, to a faceplate with high binding capability that is suitable for computer, communication, and consumer-electronics products.

### BACKGROUND

Typically, the faceplates for 3C (computer, communication, and consumer's electronics) products commonly in the market respectively include mainly a casing and a decorative film, where the casing is usually made of plastics or metal while the decorative film is formed on the surface of the casing by ways of spray coating, printing, or sputtering. When the casing of a faceplate is formed by way of injection molding, the strength of the casing may be insufficient. In order to provide the casing with sufficient strength, it is necessary to increase the thickness of the casing. Consequently, the volume of 3C products will be inevitably increased accordingly and become inconvenient to carry.

If the casing of a faceplate is made by common metal material, it will be unable to combine the casing directly onto the surface of a 3C product. Therefore, it is required to add one plastic surface layer onto the internal surface of the casing for connection with the surface of the 3C product. However, it is unable to make a firm connection between plastics and metal because of their properties. Even above two kinds of material are forced to be combined with each other, they will separate easily with each other when used after a period of time.

If the casing of a faceplate is made by aluminum magnesium alloy, it is advantageous in having preferable properties of lightweight and high strength and can be combined directly onto the external surface of a 3C product. However, when the casing is shaped, burrs and air pores may be formed on the casing's surface since the aluminum magnesium alloy is shaped by way of injection molding. Consequently, above shaped casing made by aluminum magnesium alloy should be processed by multiple procedures before other procedures of painting, paint spraying, and paint coating begin. Therefore, the processing and manufacturing cost will be greatly increased.

In order to overcome above shortcomings, inventor had the motive to study and develop the present invention. After hard research and development, the inventor provides a faceplate with high binding capability, where a firm connection can be formed between plates with different properties, sufficient strength can be obtained after the plates are connected with each other, and the processing procedures can be simplified and the cost can be reduced accordingly.

### SUMMARY OF THE DISCLOSURE

An object of the present invention is to provide a faceplate with high binding capability formed by combining plates with different properties. Thereby, it is advantageous in decreasing the thickness of the casing and thus reducing the volume of the 3C product to make it convenient for use under the condition of providing sufficient strength.

Another object of the present invention is to provide a faceplate with high binding capability formed by combining plates with different properties. Thereby, it is able to simplify the processing procedures and reduce the production cost.

Another object of the present invention is to provide a faceplate with high binding capability where a connection rod is provided to connect the metal plate and the connection element while a flexible outer layer is provided to cover the metal plate and the connection rod. Thereby, it is able to form a firm connection between the metal plate and the connection element, to make the surface of the faceplate intact, and to improve the product quality.

In order to achieve above objects, the present invention provides a faceplate with high binding capability comprising a flexible outer layer, a metal plate, and a connection element. The flexible outer layer has an external surface and an internal surface corresponding to the external surface. The metal plate has an external surface and an internal surface corresponding to the external surface. The external surface of the metal plate is adhered to the internal surface of the flexible outer layer via an adhesive layer. Besides, the metal plate is provided with at least a positioning hole throughout the metal plate and the external opening's width of the positioning hole is wider than the internal opening's width thereof. The connection element is connected to the internal surface of the metal plate and is provided with at least a connection part for being connected to 3C (computer, communication, and consumer-electronics) products.

In practice, the flexible outer layer is selected from the group including metal sheet, plastic film, leather, artificial leather, wood veneer, and fabric.

In practice, the positioning hole is a conical-shaped hole or a spot-faced hole.

In practice, the connection part is a screw hole or an insert piece.

In practice, a connection rod is positioned at the positioning hole, where one end of the connection rod passes through the positioning hole and is connected with the connection element, and the screw hole or the insert piece is provided at one end of the connection rod

The following detailed description, given by way of examples or embodiments, will best be understood in conjunction with the accompanying drawings.

### BRIEF DESCRIPTION OF THE DRAWINGS

FIG. 1 is an exploded perspective view of a first embodiment of the present invention.

FIG. 2 is a cross sectional view of the first embodiment of the present invention.

FIG. 3 is a cross sectional view of the first embodiment of the present invention where the positioning hole is a spot-faced hole.

FIG. 4 shows the use of the first embodiment of the present invention.

FIG. 5 is a cross sectional view showing part of a second embodiment of the present invention.

FIG. 6 is a cross sectional view showing part of the present invention where a connection piece is protruded from the metal plate.

### DETAILED DESCRIPTION

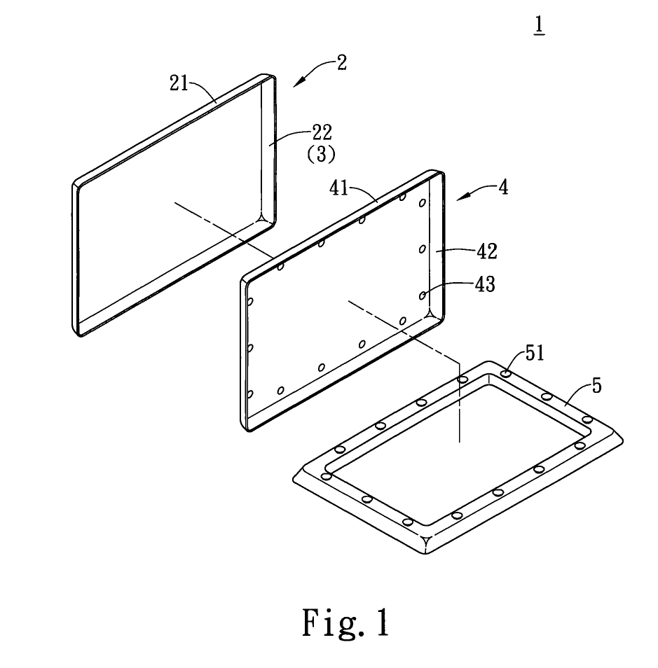

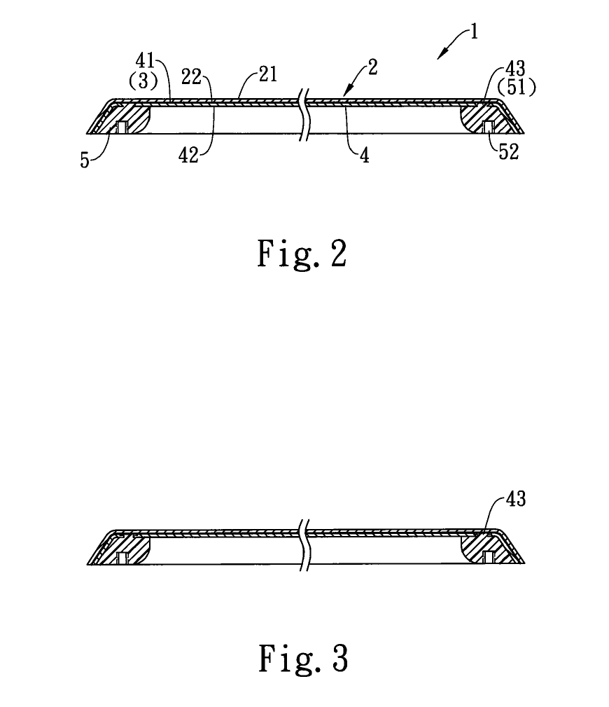

Please refer to FIGS. 1 and 2 showing a first embodiment of a faceplate with high binding capability 1 of the present invention. In this embodiment, the faceplate with high binding capability 1 comprises a flexible outer layer 2, an adhesive layer 3, a metal plate 4, and a connection element 5.

The flexible outer layer 2 is made by leather and forms a substantially rectangular casing. Besides, the flexible outer layer 2 also can be made by other kinds of material, such as metal sheet, plastic film, artificial leather, wood veneer, or woven fabric. Moreover, the flexible outer layer 2 can be in curved shape or in other three-dimensional geometric shapes. The flexible outer layer 2 includes an external surface 21 and an internal surface 22 corresponding to the external surface 21.

The metal plate 4 is a substantially rectangular casing and has an external surface 41 and an internal surface 42 corresponding to the external surface 41. The external surface 41 of the metal plate 4 is coated with adhesives to form an adhesive layer 3. Via the adhesive layer 3, the external surface 41 of the metal plate 4 is adhered to the internal surface 22 of the flexible outer layer 2. Moreover, the metal plate 4 is peripherally provided with a plurality of conical shaped holes that are throughout the metal plate 4 and used as positioning holes 43. The external opening's width of each conical shaped hole is wider than the internal opening's width thereof. In other words, the diameter of each conical shaped hole's opening on the external surface 41 of the metal plate 4 is longer than that on the internal surface 42 of the metal plate 4. In practice, the positioning holes 43 also can be spot-faced holes as shown in FIG. 3.

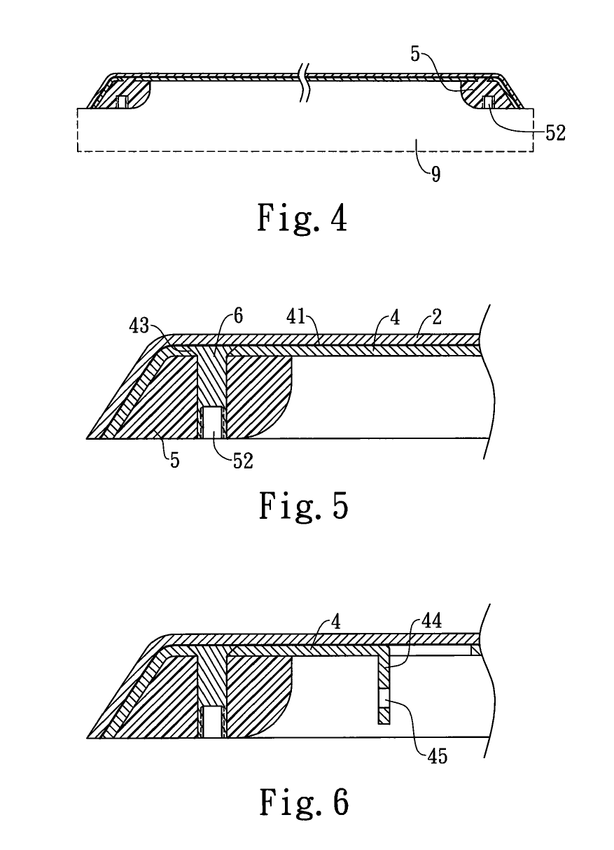

The connection element 5 is a frame formed by injection molding. When the connection element 5 is shaped via injection molding process, a plurality of positioning parts 51 are provided on the top of the peripheries of the connection element 5. The positioning parts are in inverse conical shape or in spot-faced shape and are used to establish firm connection with the positioning holes 43 respectively. Besides, as shown in FIG. 4, a plurality of screw holes are provided on the bottom of the peripheries of the connection element 5 and are used as connection parts 52 for being connected to the surface of a notebook computer 9.

Please refer to FIG. 5 showing a second embodiment of the present invention. In this embodiment, the head end of a connection rod 6 is in conical shape while the bottom end thereof is provided with a screw hole that is used as a connection part 52. When the bottom end of the connection rod 6 passes through the positioning hole 43, the conical-shaped head end is correspondingly positioned at the conical shaped positioning hole 43. Thereby, when the connection element 5 is formed by injection molding process, it covers the bottom end of the connection rod 6 to form a firm connection between the metal plate 4 and the connection element 5. When the flexible outer layer 2 is correspondingly adhered to the external surface 41 of the metal plate 4, it covers the head end of the connection rod 6 to provide the faceplate with an intact and smooth surface. In practice, the connection part 52 also can be an insert piece for being connected to 3C products such as cell phones, mice, or other electronic or communication products.

Furthermore, as shown in FIG. 6, at least a connection piece 44 is protruded from the internal surface 42 of the metal plate 4 by stamping the metal plate 4. Each connection piece 44 is provided with a through hole for being screwed to 3C products.

Therefore, the present invention has following advantages: 1. According to the present invention, the metal plate and the plastic connection element can be connected with each other via a connection rod. Consequently, they will not separate from each other after long-term usage and the quality of products can be ensured. 2. According to the present invention, by using a metal plate that is covered by a flexible outer layer, the faceplate can be provided with sufficient strength. Consequently, the whole thickness can be decreased and then the volume of 3C products can be reduced to make the faceplate convenient to use. Besides, the processing procedures for aluminum magnesium alloy also can be simplified to decrease the production cost. 3. According to the present invention, the flexible outer layer is used to cover the metal plate and the connection rod while the metal plate and the connection element are connected with each other via the connection rod. Consequently, the faceplate can be provided with an intact and smooth surface and thus be made more attractive.

As disclosed in the above description and attached drawings, the present invention can provide a faceplate with high binding capability, where the faceplate comprises plates with different properties that can be firmly connected with each other, has sufficient strength after the plates are assembled, and can be produced by simplified processing procedure in order to reduce the cost. It is new and can be put into industrial use.

Although the embodiments of the present invention have been described in detail, many modifications and variations may be made by those skilled in the art from the teachings disclosed hereinabove. Therefore, it should be understood that any modification and variation equivalent to the spirit of the present invention be regarded to fall into the scope defined by the appended claims.

What is claimed is:

1. A faceplate with high binding capability, comprising:
a flexible outer layer, having an external surface and an internal surface corresponding to the external surface;
a metal plate, having an external surface and an internal surface corresponding to the external surface, where the external surface of the metal plate is adhered to the internal surface of the flexible outer layer via an adhesive layer; the metal plate is provided with at least a positioning hole throughout the metal plate and the external opening's width of the positioning hole is wider than the internal opening's width thereof; and
a connection element, combined to the internal surface of the metal plate and provided with at least a connection part for being connected to 3C (computer, communication, and consumer-electronics) products.

2. The faceplate with high binding capability as claimed in claim 1, wherein the flexible outer layer is selected from the group including metal sheet, plastic film, leather, artificial leather, wood veneer, and fabric.

3. The faceplate with high binding capability as claimed in claim 2, wherein the positioning hole is a conical-shaped hole.

4. The faceplate with high binding capability as claimed in claim 2, wherein the positioning hole is a spot-faced hole.

5. The faceplate with high binding capability as claimed in claim 2, wherein the connection part is a screw hole.

6. The faceplate with high binding capability as claimed in claim 5, wherein a connection rod is positioned at the positioning hole, where one end of the connection rod passes through the positioning hole and is connected with the connection element, and the screw hole is provided at one end of the connection rod.

7. The faceplate with high binding capability as claimed in claim 2, wherein the connection part is an insert piece.

8. The faceplate with high binding capability as claimed in claim 7, wherein a connection rod is positioned at the positioning hole, where one end of the connection rod passes through the positioning hole and is connected with the connection element, and the insert piece is disposed at one end of the connection rod.

9. The faceplate with high binding capability as claimed in claim 2, wherein at least a connection piece is protruded from the internal surface of the metal plate for being connected to 3C products.

10. The faceplate with high binding capability as claimed in claim 1, wherein the positioning hole is a conical-shaped hole.

11. The faceplate with high binding capability as claimed in claim 1, wherein the positioning hole is a spot-faced hole.

12. The faceplate with high binding capability as claimed in claim 1, wherein the connection part is a screw hole.

13. The faceplate with high binding capability as claimed in claim 12, wherein a connection rod is positioned at the positioning hole, where one end of the connection rod passes through the positioning hole and is connected with the connection element, and the screw hole is provided at one end of the connection rod.

14. The faceplate with high binding capability as claimed in claim 1, wherein the connection part is an insert piece.

15. The faceplate with high binding capability as claimed in claim 14, wherein a connection rod is positioned at the positioning hole, where one end of the connection rod passes through the positioning hole and is connected with the connection element, and the insert piece is disposed at one end of the connection rod.

16. The faceplate with high binding capability as claimed in claim 1, wherein at least a connection piece is protruded from the internal surface of the metal plate for being connected to 3C products.
